(19) United States
(12) Patent Application Publication
(10) Pub. No.: US 2015/0180426 A1
(43) Pub. Date: Jun. 25, 2015

(54) ADAPTIVE RECEIVER/TRANSMITTER AMPLIFIER CIRCUIT

(71) Applicant: AURIGA MEASUREMENT SYSTEMS, LLC, Chelmsford, MA (US)

(72) Inventor: Nickolas D. Kingsley, Andover, MA (US)

(21) Appl. No.: 14/543,767

(22) Filed: Nov. 17, 2014

Related U.S. Application Data
(60) Provisional application No. 61/905,654, filed on Nov. 18, 2013.
(60) Provisional application No. 61/905,658, filed on Nov. 18, 2013.
(60) Provisional application No. 61/905,624, filed on Nov. 18, 2013.

(51) Int. Cl. H03F 1/30; H03F 3/21; H03F 1/56; H03F 3/193

(52) U.S. Cl. CPC H03F 1/30; H03F 3/193; H03F 3/21; H03F 1/565; H03F 2200/451; H03F 2203/21127; H03F 2200/387

(57) ABSTRACT

A SMART amplifier circuit is disclosed. The amplifier circuit comprises a processor configured to receive a state control signal and generate a plurality of control signals, a power amplifier configured to provide an amplified RF signal that is a function of the RF input signal and the first control signal, and a tunable matching network configured to receive a second control signal and to provide a tuned, amplified RF output signal as an output that is a function of the amplified RF signal and the second control.

### CROSS-REFERENCE TO RELATED APPLICATIONS

This application claims the benefit under 35 U.S.C. §119(e) of co-pending U.S. Provisional Patent Application No. 61/905,654 titled “SENSING, MANAGING, ADAPTING RECEIVER/TRANSMITTER AMPLIFIER CIRCUIT” and filed on Nov. 18, 2013; co-pending U.S. Provisional Patent Application No. 61/905,658 titled “TUNABLE MATCHING NETWORK CIRCUIT” and filed on Nov. 18, 2013; and of co-pending U.S. Provisional Patent Application No. 61/905,624 titled “DUAL PATH RF AMPLIFIER CIRCUIT HAVING INCREASED POWER ADDED EFFICIENCY (PAE) AND INCREASED LINEARITY AT SATURATION” and filed on Nov. 18, 2013, all of which are herein incorporated by reference in their entirety.

### FIELD OF THE INVENTION

The subject matter described herein relates generally to radio frequency (RF) circuits and, more particularly, to sensing, managing, adapting, receiver/transmitter amplifier circuits.

### BACKGROUND

As is known in the art, radio frequency (RF) transmit systems commonly employ RF amplifying devices to convert low-power RF signals into higher-power RF signals. These higher-power RF signals can be used, for example, to drive an antenna of a transmitter. Typical amplifiers lack the ability to adjust their output performance over a wide range of operating conditions.

### SUMMARY OF INVENTION

Aspects and embodiments are directed to an amplifier circuit, device, system, and concepts appropriate for use in a system where peak performance is needed over a wide range of operating conditions. In particular, disclosed is an amplifier device capable of providing near-optimal (or ideally optimal) linearity performance, power output performance, and power added efficiency performance over a desired bandwidth for a plurality of operating conditions. The amplifier device provides an all-in-one amplifier circuit solution with any or all of additional functionality, improved performance, smaller size, lower weight, reduced power consumption, and lower cost than existing conventional amplifier circuits having similar functionality.

Aspects and embodiments are also directed to a Tunable Matching Network (TMN) circuit, device, system, and concepts which can provide a tunable impedance. The TMN can provide improved RF circuit performance by providing a variable input and/or output impedance to the RF circuit. For example, by changing control voltages in the TMN circuit, the impedance of the TMN circuit can be changed to enable the amplifier circuit to achieve any of desired power performance, desired gain performance, desired bandwidth performance, desired Power Added Efficiency performance, linearity performance, noise performance, or a combination of any or all of these conditions.

One embodiment of an amplifier circuit comprises a processor configured to receive a state control signal and generate a plurality of control signals, a power amplifier configured to provide an amplified RF signal that is a function of an RF input signal and the first control signal, and a tunable matching network at an output of the power amplifier that is configured to receive a second control signal and to provide a tuned, amplified RF output signal as an output that is a function of the amplified RF signal and the second control signal.

One embodiment of the amplifier further comprises a first coupler having an input coupled to an input of the power amplifier and an output for providing a coupled signal from the input of the power amplifier, and a first analog-to-digital converter (ADC) having an input coupled to the output of the first coupler and having an output providing a first ADC signal to the processor. According to aspects of this embodiment, the processer can be configured to receive first ADC signal and to provide the first control signal and the second control signal as function of the first ADC signal.

One embodiment of the amplifier further comprises a second coupler having an input coupled to an output of the tunable matching network and an output for providing a coupled signal from the output of the tunable matching network, and a second analog-to-digital converter (ADC) having an input coupled to the output of the second coupler an output providing a second ADC signal to the processor. According to aspects of this embodiment, the processer can be configured to receive the second ADC signal and to provide the first control signal and the second control signal as function of the second ADC signal.

According to various embodiments, either one of or a combination of both of the first and second couplers and ADC can be provided.

According to one embodiment of the amplifier, the processor is configured, in response to the a state control signal, to provide the first control signal to set the bias of the power amplifier to a maximum operating value so as to provide a maximum power out from the power amplifier, and to provide the second control signal to the tunable matching network to provide a Maximum Power Out (Max Pout) impedance to the output of the Power Amplifier.

According to one embodiment of the amplifier, the processor is configured, in response to the a state control signal, to provide the first control signal to set the bias of the power amplifier to any of class F, F⁻¹, or J operation, and to provide the second control signal to the tunable matching network to provide a Maximum Power Added Efficiency (Max PAE) impedance to the output of the Power Amplifier.

According to one embodiment of the amplifier, the processor is configured, in response to the a state control signal, to provide the first control signal to set the bias of the power amplifier to any of class AB or B operation, and to provide the second control signal to the tunable matching network to provide a Maximum Power Added Efficiency (Max PAE) impedance to the output of the Power Amplifier.

According to one embodiment of the amplifier, the processor is configured, in response to the a state control signal, to provide the first control signal to set the bias of the power amplifier so as to reduce the spurious nature of the output signal from the Power Amplifier, and to provide the second control signal to the tunable matching network to provide a minimum third order intermodulation (Min IM3) impedance to the output of the Power Amplifier.

According to one embodiment of the amplifier, the processor is configured, in response to the a state control signal, to provide the first control signal to set the bias of the power amplifier so as to provide a third order intercept point IM3 at a desired operating power, and to provide the second control signal to the tunable matching network to provide a minimum third order intercept (Min IM3) impedance to the output of the Power Amplifier.

According to one embodiment of the amplifier, the processor is configured, in response to the a state control signal, to provide the first control signal to set the bias of the power amplifier to reduce the voltage output of the amplified signal at the output of the power amplifier, and to provide the second control signal to the tunable matching network to provide a Minimum Noise (NFₘᵢₙ) impedance to the output of the Power Amplifier.

According to aspects of various embodiments, the processor can be configured to provide the first and second control signal to provide any one of or any combination of modes of operation of the power amplifier and the impedances presented to the output of the power amplifier.

According to another embodiment, an amplifier circuit includes a state control line coupled to an output of a system configured to generate a state control signal. The amplifier circuit also includes a processor configured to generate a plurality of control signals as a function of the state control signal. The amplifier circuit additionally includes a power amplifier configured to receive an RF signal as a first input and a first control signal as a second input and to provide an amplified signal as an output. The amplifier circuit can further include a tunable matching network coupled to an output of the power amplifier that is configured to receive a second control signal as a first input and the amplified signal from the power amplifier as a second input, and generate a tuned amplified signal as an output.

According to one embodiment of the SMART amplifier circuit, the power amplifier comprises an input coupler configured to receive an RF input signal and to generate at least two coupled signals, a first RF amplifier configured to receive and amplify a first one of the at least two coupled signals to generate a first amplified signal, the first RF amplifier being biased into a first class of operation, a second RF amplifier configured to receive and amplify a second one of the at least two coupled signals to generate a second amplified signal, the second RF amplifier being biased into a second class of operation, and an output coupler configured to receive the first and second amplified signals and to generate an amplified output signal based on the first and second amplified signals, wherein a power ratio between the first and second RF amplifiers is selected based on biasing of the first and second RF amplifiers, the first class of operation, and the second class of operation.

According to one example of the power amplifier, the first class of operation is one of class A, class AB, and class B, and the second class of operation is class C. In another example of the power amplifier, the power ratio is 1:1. In one example, the input coupler and the output coupler are 3 dB couplers.

In another example of the power amplifier, the first class of operation is the same as the second class of operation, the first RF amplifier has a normalized power rating of 1, and the second RF amplifier has a normalized power rating of N, such that the power ratio is 1:N. In one example of the power amplifier, the input coupler has an input coupling factor selected to match the power ratio. In another example of the power amplifier, the output coupler has an output coupling factor selected to match the power ratio.

In another example of the power amplifier, the input coupler is configured to provide the first one of the at least two coupled signals at a first port with a coupling factor of N/(N+1), and to provide the second one of the at least two coupled signals at a second port with a coupling factor of 1/(N+1), wherein the first RF amplifier is connected to the first port to receive the first one of the at least two coupled signals, and the second RF amplifier is connected to the second port to receive the second one of the at least two coupled signals. In one example of the power amplifier, the output coupler is a 3 dB coupler. In another example, the output coupler has a first input port connected to an output of the first RF amplifier to receive the first amplified signal, and a second input port connected to an output of the second RF amplifier to receive the second amplified signal, and the output coupler is configured with a coupling factor of N/(N+1) at the second input port and a coupling factor of [1−N/(N+1)] at the first input port. In another example of the power amplifier, output coupler has a first input port connected to an output of the first RF amplifier to receive the first amplified signal, and a second input port connected to an output of the second RF amplifier to receive the second amplified signal, and the output coupler is configured with a coupling factor of 1/(N+1) at the second input port and a coupling factor of [1−1/(N+1)] at the first input port.

In one example of the power amplifier, the first RF amplifier and the second RF amplifier are substantially the same and are biased differently such that the power ratio is less than or greater than one.

According to another embodiment of the SMART amplifier circuit, the power amplifier circuit comprises an input coupler configured to receive an RF input signal and to generate a plurality of coupled signals, a plurality of RF amplifiers each connected to the input coupler and configured to receive and amplify one of the plurality of coupled signals to generate a corresponding plurality of amplified signals, each of the plurality of RF amplifiers being configurable as to a class of operation and biasing, and an output coupler connected to the plurality of RF amplifiers and configured to receive the plurality of amplified signals and to generate an amplified output signal from the plurality of amplified signals, the amplified output signal being based on a combination of a selected class of operation of each of the plurality of RF amplifiers, the biasing of each of the plurality of RF amplifiers, and a power ratio between the plurality of RF amplifiers.

In one example of the power amplifier, the plurality of RF amplifiers includes a first RF amplifier having a normalized power rating of 1, a second RF amplifier having a normalized power rating of X, and a third RF amplifier having a normalized power rating of Y, and wherein the power ratio is 1:X:Y. In another example of the power amplifier, the input coupler has an input coupling factor selected to match the power ratio. In another example of the power amplifier, the output coupler has an output coupling factor selected to match the power ratio. In another example of the power amplifier, the plurality of RF amplifiers are biased such that the power ratio is less than or greater than one.

According to one embodiment of the amplifier, the tunable matching network circuit, comprises a first sub-circuit implementing a reconfigurable shunt RC circuit, a second sub-circuit implementing a reconfigurable shunt RL circuit; a third sub-circuit implementing a reconfigurable series RL circuit, a fourth sub-circuit implementing a reconfigurable series RC circuit, and a fifth sub-circuit implementing a series short circuit for bypassing the third sub-circuit and the fourth sub-circuit. According to aspects of this embodiment, each sub-circuit comprises one or more FET's configured to provide a variable impedance for adjusting a tunable range of the tunable matching network circuit.

According to aspects of this embodiment of the amplifier, the first sub-circuit comprises at least one field effect transistor (FET) in series with a capacitance to provide a shunt RC sub-circuit. According to aspects of this embodiment, the second sub-circuit comprises at least one field effect transistor (FET) in series with an inductor to provide a shunt RL sub-circuit. According to aspects of this embodiment, the third sub-circuit comprises at least one field effect transistor (FET) in series with an inductor to provide a series RL sub-circuit. According to aspects of this embodiment, the fourth sub-circuit comprises at least one field effect transistor (FET) in series with a capacitor to provide a series RC sub-circuit. According to aspects of this embodiment, the fifth sub-circuit comprises at least one field effect transistor (FET) that can be varied with a gate control voltage to provide substantially a short circuit so as to bypass the third and fourth sub-circuits or an open circuit so as to not bypass the third and fourth sub-circuits.

According to aspects of this embodiment of the amplifier, the Tunable Matching Network (TMN) can comprise any one of the first sub-circuit, the second sub-circuit, the third sub-circuit, the fourth sub-circuit, and the fifth sub-circuit and any combination of the first sub-circuit, the second sub-circuit, the third sub-circuit, the fourth sub-circuit, and the fifth sub-circuit.

According to aspects of this embodiment of the amplifier, the at least one field effect transistor (FET) of any of the first sub-circuit, the second sub-circuit, the third sub-circuit, the fourth sub-circuit, and the fifth sub-circuit can be varied with a gate control voltage to provide the variable impedance value that can be varied to provide substantially an open circuit, substantially a short circuit, or an impedance value there between.

According to aspects of this embodiment of the amplifier, at least one of the first sub-circuit, second sub-circuit, third sub-circuit, fourth sub-circuit, and fifth sub-circuit comprises at least two stacked FETs, a floating gate bias voltage source, and a plurality of resistors arranged to isolate the floating gate bias voltage source.

According to one embodiment, a tunable matching network (TMN) circuit comprises a first sub-circuit implementing a reconfigurable shunt RC circuit, a second sub-circuit implementing a reconfigurable shunt RL circuit; a third sub-circuit implementing a reconfigurable series RL circuit, a fourth sub-circuit implementing a reconfigurable series RC circuit, and a fifth sub-circuit implementing a series short circuit for bypassing the third sub-circuit and the fourth sub-circuit. According to aspects of this embodiment, each sub-circuit comprises one or more FET's configured to provide variable impedance for adjusting a tunable range of the tunable matching network circuit.

According to aspects of this embodiment of the tunable matching network (TMN) circuit, the first sub-circuit comprises at least one field effect transistor (FET) in series with a capacitance to provide a shunt RC sub-circuit. According to aspects of this embodiment, the second sub-circuit comprises at least one field effect transistor (FET) in series with an inductor to provide a shunt RL sub-circuit. According to aspects of this embodiment, the third sub-circuit comprises at least one field effect transistor (FET) in series with an inductor to provide a series RL sub-circuit. According to aspects of this embodiment, the fourth sub-circuit comprises at least one field effect transistor (FET) in series with a capacitor to provide a series RC sub-circuit. According to aspects of this embodiment, the fifth sub-circuit comprises at least one field effect transistor (FET) that can be varied with a gate control voltage to provide substantially a short circuit so as to bypass the third and fourth sub-circuits or an open circuit so as to not bypass the third and fourth sub-circuits.

According to aspects of this embodiment of the tunable matching network (TMN) circuit, the Tunable Matching Network (TMN) can comprise any one of the first sub-circuit, the second sub-circuit, the third sub-circuit, the fourth sub-circuit, and the fifth sub-circuit and any combination of the first sub-circuit, the second sub-circuit, the third sub-circuit, the fourth sub-circuit, and the fifth sub-circuit.

According to aspects of this embodiment of tunable matching network (TMN) circuit, the at least one field effect transistor (FET) of any of the first sub-circuit, the second sub-circuit, the third sub-circuit, the fourth sub-circuit, and the fifth sub-circuit can be varied with a gate control voltage to provide the variable impedance value that can be varied to provide substantially an open circuit, substantially a short circuit, or an impedance value there between.

According to aspects of this embodiment of the tunable matching network (TMN) circuit, at least one of the first sub-circuit, second sub-circuit, third sub-circuit, fourth sub-circuit, and fifth sub-circuit comprises at least two stacked FETs, a floating gate bias voltage source, and a plurality of resistors arranged to isolate the floating gate bias voltage source.

According to another embodiment, the TMN circuit includes a first sub-circuit for implementing a shunt capacitance and configured to be a reconfigurable shunt RC circuit. The (TMN) circuit can further include a second sub-circuit for implementing a shunt inductance and configured to be a reconfigurable shunt RL circuit. The TMN circuit can also include a third sub-circuit for implementing a series inductance and configured to be a reconfigurable series RL circuit. The TMN circuit can additionally include a fourth sub-circuit for implementing a series capacitance and configured to be a reconfigurable RC circuit. The TMN circuit can further include a short circuit for bypassing the fourth sub-circuit and the fifth sub-circuit, wherein each sub-circuit comprises one or more FET's configured to provide a variable resistance for adjusting a tunable range of the tunable matching network circuit.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1A is a block diagram of one embodiment of a SMART amplifier circuit having a processor, a state-control line, a power amplifier, a tunable matching network, and a plurality of control lines;

FIG. 1B is a block diagram of another embodiment of a SMART amplifier circuit having a processor, a state-control line, a power amplifier, a tunable matching network, a plurality of control lines, a temperature sensor, and a plurality of analog-to-digital converters;

FIG. 2 illustrates an example impedance plot on a Smith Chart of an exemplary tunable matching network of amplifier circuit of FIG. 1;

FIG. 3 is a block diagram of one example of a power amplifier circuit including two amplifiers with a 1:N power ratio, according to aspects of the SMART amplifier circuit;

FIG. 4 is a block diagram of another example of a power amplifier circuit including two amplifiers with a 1:N power ratio and using coupling ratios of N/(N+1) and 1/(N+1) corresponding to amplifier ratios of 1 and N, according to aspects of the SMART amplifier circuit;

FIG. 5 is a graph of radio frequency (RF) output power as a function of RF input power, showing examples of power curves for the amplifiers and amplifier circuit of FIG. 3, according to aspects of the SMART amplifier circuit; and

FIG. 6 is a graph of output power back-off from output saturation power (Psat) versus third order intermodulation product (IM3) amplitude, illustrating that examples of the power amplifier circuits according to aspects of the SMART amplifier circuit achieve linearity improvement deep into saturation while maintaining high efficiency;

FIG. 7 is a schematic diagram of one exemplary Tunable Matching Network (TMN) circuit;

FIG. 8A is a schematic diagram of one embodiment of a sub-circuit of the TMN circuit of FIG. 7;

FIG. 8B is a schematic diagram of another embodiment of a sub-circuit of the TMN circuit of FIG. 7;

FIG. 9 is Smith Chart graph illustrating a customizable tunable range of a single sub-circuit of the TMN:

FIG. 10 is a Smith Chart graph illustrating example measurements of the exemplary TMN circuit of FIG. 7;

FIG. 11 is a graph illustrating the response versus time of the exemplary tunable matching network of FIG. 7 in response to various control signals received from a control line of the exemplary amplifier circuit of FIG. 1; and

FIG. 12 is graph illustrating an example output of the exemplary amplifier circuit of FIG. 1.

### DETAILED DESCRIPTION

Aspects and embodiments are directed to an amplifier circuit, device, system, concepts and method thereof appropriate for use in a system where peak performance is needed over a wide range of operating conditions. In particular, disclosed is an amplifier device capable of providing near-optimal (or ideally optimal) linearity performance, power output performance, and power added efficiency performance over a desired bandwidth for a plurality of operating conditions. The amplifier device can have simultaneous transmit and receive radar and knowledge-aided adjustment using previously obtained information. The amplifier device provides an all-in-one amplifier circuit solution with a smaller size, lower weight, reduced power consumption, and lower cost than existing conventional amplifier circuits having similar functionality.

It is to be appreciated that embodiments of the methods and apparatuses discussed herein are not limited in application to the details of construction and the arrangement of components set forth in the following description or illustrated in the accompanying drawings. The methods and apparatuses are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms.

As used herein, the term “processor” is used to describe an electronic circuit that performs a function, an operation, or a sequence of operations. The function, operation, or sequence of operations can be hard coded into the electronic circuit or soft coded by way of instructions held in a memory device. A “processor” can perform the function, operation, or sequence of operations using digital values or using analog signals.

In some embodiments, the “processor” can be embodied in or realized as an application specific integrated circuit (ASIC), which can be an analog ASIC or a digital ASIC. In some embodiments, the “processor” can be embodied in or realized as a microprocessor with associated program memory. In some embodiments, the “processor” can be embodied in or realized as a discrete electronic circuit, which can be an analog or digital.

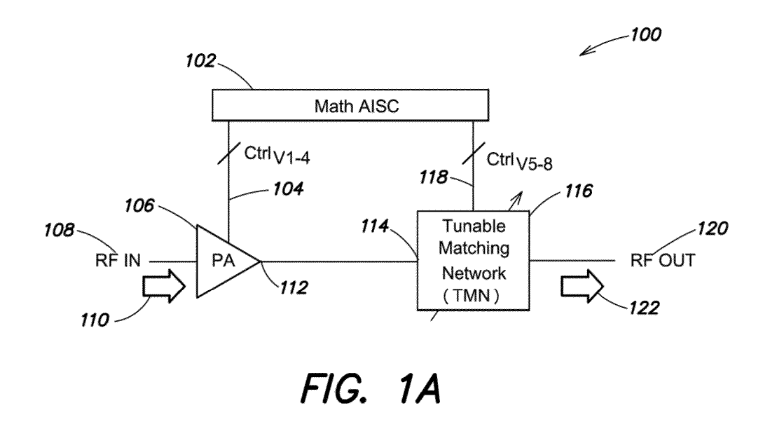

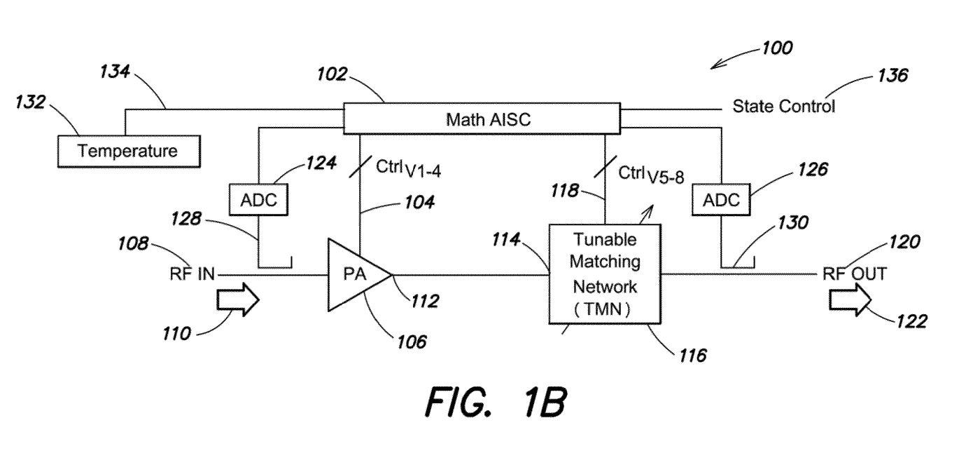

Referring now to FIG. 1A, which is a block diagram of one exemplary embodiment of a sensing, managing, adapting, receiver/transmitter (SMART) amplifier circuit 100 that includes a math ASIC/System CPU 102, an amplifier 106, and a tunable matching network (TMN) 116. AURIGA SMART™ is a pending trademark application of Auriga Microwave. Two Executive Drive, Suite 305, Chelmsford, Mass. 01824 USA. The processor 102 has one or more output control lines 104 coupled to a terminal (e.g. a control terminal) of an amplifier 106, and one or more control lines 118 of math ASIC/System CPU 102 are coupled to a terminal (e.g. a control terminal) of the tunable matching network (TMN) 116. An RF input 108 of the power amplifier is coupled to an input of SMART amplifier circuit 100 to receive an input signal 110 and an RF output 112 of the power amplifier 106 provides an amplified output signal that is coupled to an input 114 of the tunable matching network 116. An output 120 of the tunable matching network 116 provides a tuned, amplified output signal 122 that is coupled to an output of SMART amplifier circuit 100.

Referring now to FIG. 1B, which is a block diagram of another embodiment of a SMART amplifier circuit having processor 102, state-control line 136, power amplifier 106, tunable matching network 116, the plurality of control lines 104, 118, and any or all of a temperature sensor 132, analog-to-digital converters 124, 126 and couplers 128, 130. In particular, in some embodiments, the SMART amplifier circuit 100 further includes an analog-to-digital converters (ADC) 124, that is coupled by a coupler 128 to the RF input 108 of amplifier 106, and an ADC 126 that is coupled by a coupler 130 to the RF output 120 of the tunable matching network 116. In some embodiments, the SMART amplifier circuit 100 can alternatively or further include a temperature sensor 132 for sensing a temperature of the environment of the SMART amplifier circuit providing an output signal on line 134 coupled to math ASIC/System CPU 102. In some embodiments, the SMART amplifier circuit 100 can alternatively or further include a state control line 136 coupled to a control input terminal of math ASIC/System CPU 102. Thus, the Math ASIC/System CPU 102 can optionally be coupled to receive a temperature signal from the temperature sensor 132 and a state control signal from state control line 136, which can be a state control digital bus. The state control signal can be received from a system in which the SMART amplifier circuit 100 is being used to receive in real-time control information concerning the performance characteristics to be provided by the SMART amplifier circuit 100 under predetermined conditions including peak power mode, high-efficiency mode, high-linearity mode and minimum noise mode. In some embodiments, the Math ASIC/System CPU 102 can be a dedicated Math ASIC or processor for the SMART amplifier circuit 100. In some embodiments, the state control signal can be provided by the system in which the SMART amplifier module 100 is used. In some embodiments, the processor 102 can be a system CPU or alternative processor 102 (collectively a “processor”) of the system where the SMART amplifier circuit 100 is being used and need not be a separate processor, to provide for straightforward integration of the SMART amplifier circuit with the overall system.

The Math ASIC/System CPU 102 is configured to provide one or more control signals to the power amplifier 106 and one or more control signals to the tunable matching network 116 via control lines 104, 118 to achieve optimal performance. The control signals can be, for example, based upon a preconfigured desired state or determined dynamically from an algorithm, which can in some embodiments take into account any or all of the input waveform, an ideal matching condition, a bandwidth desired (e.g., narrow-band or broad-band), the temperature signal received from a temperature sensor 132, and/or the state control signal received from the state control line 136. The control signals can be configured to set the gate and drain voltages of the power amplifier 106 and the control voltages of the tunable matching network 116.

The Math ASIC/System CPU 102 can optionally be further coupled to either or both of ADCs 124, 126, which can be configured to provide, for example, a digital signal indication of the RF input power to the power amplifier 106 and the RF output power from tunable matching network 116, respectively. For such arrangement, the couplers 128, 130 can also be coupled to the RF input 108 of the amplifier 106 and/or the RF output 120 of the tunable matching network, and a port of the couplers 128, 130 can also be coupled the input of the ADCs 124, 126 to provide real-time feedback to the Math ASIC/System CPU 102 for evaluation.

In one exemplary operational embodiment, the power amplifier 106 receives one or more RF input signals110 and a digital control signal 104 provided by the processor 102, which is a signal derived from either or both of the measurement of signal 110 provided by ADC 1124 to the processor 102 and the state control signal 136, and in response thereto, the power amplifier 106 provides an amplified signal at output 112 to the input 114 of the tunable matching network 116. It is appreciated that the power amplifier 1.06 of the SMART amplifier circuit 100 can be any amplifier configured for bias configurability, for example so as to be able to be biased to any or all of the following modes: to place a third-order intermodulation (IM3) point of the power amplifier at substantially any desired back-off level; to provide 10-20 dB of multi-octave linearity improvement near saturation, to operate in peak power mode, to operate in a high-efficiency mode, and to operate in a minimum noise mode. It is appreciated that any number of amplifiers known to those of skill in the art, including multi-stage amplifiers, can be used as the Power Amplifier 106 of the SMART amplifier circuit 100. At least one exemplary Power Amplifiers will be described herein.

The tunable matching network 116 receives the amplified signal provided at output 112 from the power amplifier 106 and receives a control signal on the control line 118, which is derived from either or both of the digital signal provided from the ADC 126 to the processor 102 and the state control signal 136, and in response thereto the tunable matching network 116 can be tuned to a desired impedance based on the control signal on line 118 to provide an optimized impedance to the output of the power amplifier 106 to provide a tuned, amplified signal 122 at the RF output 120 of the tunable matching network.

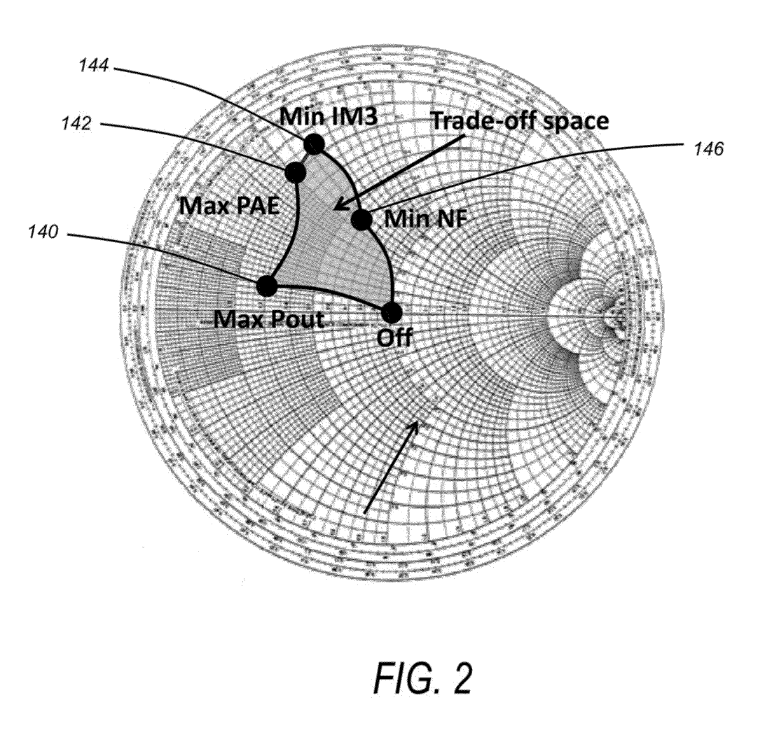

It is appreciated that the tunable matching network 116 can be any tuning matching network that can provide a tunable impedance range that is customizable and that can be configured to provide all optimal impedances for any or all of the various desired modes of operation (operation states) of the amplifier 106 and for the SMART amplifier circuit 100, and that can provide an output of the amplifier 106 tuning process that occurs almost in real-time. For example, as shown in the Smith chart plot of FIG. 2, there is illustrated one example of a capability of a tunable matching network that can tune the impedance provided at the output of the amplifier 106 along a conductance circle on the Smith Chart according to the voltage control 118, for example, so that a desired impedance at the output of the power amplifier matches any or all of the following impedances: Maximum Power Out (Max Pout) impedance 140, Maximum Power Added Efficiency (Max PAE) impedance 142, Minimum third order intercept (Min IM3) impedance 144, and Minimum Noise (NFₘᵢₙ) impedance 146. At least one exemplary tunable matching network (TMN) for providing such impedances will be described herein.

Returning now to FIGS. 1A-1B, thus in operation the SMART amplifier circuit 100 can be configured to adapt between multiple operation states, which can include a peak power state, a peak efficiency state, a peak linearity state, a minimum noise state, and a specialty state. According to one embodiment of the SMART amplifier 100, the optimal bias signals/conditions for the amplifier 106 and the optimal impedance signals/values for the tunable matching network 116 for each of the performance (operation) states desired can be programmed into the Math ASIC/System CPU 1. This may be accomplished, for example, as a look-up table, or a series of equations, or in any manner known to those of skill in the art.

According to aspects of some embodiments, the temperature sensor 132 can be part of the SMART amplifier circuit 100 to determine the temperature of the environment of SMART amplifier and to provide the temperature signal 134 to the processor 102, so that changes of operation of either or both of the power amplifier 106 and the tunable matching network 116 with temperature also can be accounted for by the programmed bias signals 104, 118 to the power amplifier 106 and the tunable matching network 116 so as to also allow for the Math ASIC/System CPU 102 to correct for temperature effects of the environment of the SMART amplifier 100. It is appreciated in the case of the amplifier 106 corresponding to a multi-stage power amplifier, that each stage of the multi-stage amplifier can have its own reconfigurable bias parameters that are stored in the processor 102. Likewise, it is appreciated in the case an N-way power amplifier is used (e.g., such as a balun combined or coupler combined Doherty Amplifier), that each amplifier stage can have its own reconfigurable bias points stored in the processor 102. Additionally, it is appreciated that in some embodiments multiple tuning matching networks 5 can be used between multiple stages of the Power Amplifier 106, for example, after each amplifier in an N-way amplifier configuration.

Exemplary operating states of the SMART amplifier circuit 100 will now be discussed. It is to be appreciated that the SMART amplifier circuit 100 can be configured to operate in any individual or any combination of these operating states. In the peak power state, for example, the Math ASIC/System CPU 102 of the SMART amplifier circuit 100 can be configured to provide signals on the control lines 104, 118, respectively, to set the bias of the Power Amplifier 106 to a maximum operating value so as to provide a maximum power out, and the Power Amplifier 106 can also be configured to operate in a traditional hybrid performance state, and the tunable matching network 116 can be configured to provide a Maximum Power Out (Max Pout) impedance 140 to the output 112 of the Power Amplifier 106.

In a peak efficiency state where narrow band functionality is desired, for example, the Math ASIC/System CPU 102 can be configured to reduce the output voltage provided at the output 112 of the power amplifier 106 and the impedance presented by the tunable matching network 116 via the control lines 104, 118, respectively, such that the Power Amplifier 106 and thus the SMART amplifier circuit 100 is biased to any of class F, F⁻¹, or J operation and the Maximum Power Added Efficiency (Max PAE) impedance 142 is provided to the output of the Power Amplifier 106. Alternatively, in a peak efficiency state where broad band functionality is desired, the Math ASIC/System CPU 102 can be configured to provide the control lines104, 118, respectively, to reduce the output voltage provided at the output of the power amplifier 106 and the impedance presented by the tunable matching network 116 such that the SMART amplifier circuit 100 is biased to any of class AB or B operation and the Maximum Power Added Efficiency (Max PAE) impedance 142 is provided to the output of the power amplifier 106. It is appreciated that while the above-described amplifier operating in the above-described states of operation are preferred states of operation, the power amplifier (106) can also be any of an envelope-tracked power amplifier, a pulse width modulated power amplifier or other power amplifiers known to those of skill in the art that operate in other operation states.

In a peak linearity state where narrow band functionality is desired, for example, the Math ASIC/System CPU 102 can be configured to provide control signals to the power amplifier 106 and tunable matching network 116 via the control lines 104, 118, respectively, in such a manner to reduce the spurious nature, if any, of the output signal from the Power Amplifier 112 and thus the tunable amplified output signal provided at the output 116 of the tunable matching network 5, respectively. Alternatively, in a peak linearity state where broad band functionality is desired, the Math ASIC/System CPU 102 can be configured to provide control signals to the power amplifier 106 and tunable matching network 116 via the control lines 104, 118, so that the power amplifier 106 can be configured to produce an amplified signal at the output 112 having a third order intermodulation point IM3 at a desired operating power and the impedance presented at the output of the Power Amplifier is a Minimum third order intermodulation (Min IM3) impedance 144.

In a minimum noise state, the Math ASIC/System CPU 102 can be configured to provide control signals to the power amplifier 106 and tunable matching network 116 via the control lines 104, 118, to reduce the voltage output of the tunable amplified signal at the output of the power amplifier 106 and thus at the output 120 of the tunable matching network 116 by setting the bias setting of the Power Amplifier 106 to run at a low noise bias and the tuning matching network 116 can be configured to provide a Minimum Noise (NFₘᵢₙ) impedance 146 to the output 112 of the power amplifier 106.

In a “specialty” state, the SMART amplifier circuit 100 can, for example, be optimized for commercial waveforms, including Long-Term Evolution (LTE), or military waveforms, including soldier radio waveform (SRW), wideband network waveform (WNW), and Link-16 Missile and Tactical Terminal applications. Each of these waveforms has a unique operating behavior that can be optimized for, including peak power, average power, crest factor, channel bandwidth, and operating frequency.

According to aspects of some embodiments, the SMART amplifier circuit 100 can be further configured to operate in a state where the temperature sensor 132 is also coupled to the Math ASIC/System CPU 102 and configured to provide a temperature reading signal 134 to the Math ASIC/System CPU 102 to enable the SMART amplifier circuit 100 to also compensate for temperature variations of either or both the power amplifier 106 and the tunable matching network 116. According to aspects of some embodiments, an output of the ADC 124 can be coupled to the Math ASIC/System CPU 102 and an input of the ADC can be coupled by coupler 128 to the input 108 of the power amplifier 4, so as to determine the input power level (or other characteristics) of the input signal 110 to the power amplifier, and the processor 102 can be configured to receive either or both of the power level signal at the output of the ADC 124 and the temperature signal 134 and provide the bias level signal 104 to the power amplifier 106 that is derived from these signals. With this arrangement, the SMART amplifier circuit is configured to monitor the input power level digital signal received from the ADC 124 and optionally the temperature level signal and in real-time and adjust the bias signal 104 to the power amplifier 106 to adjust the amplified signal provided at the output 112 of the power amplifier 106 in response thereto. Additionally, for such embodiments, the output of the ADC 126 can be coupled to the Math ASIC/System CPU 102 and the input of the ADC 126 can be coupled to the output 120 of the tunable matching network 116 via the coupler 130. With this arrangement, the processor 102 can be configured to receive either or both of the output power level signal and the temperature signal 134 and provide the bias level signal 118 to the tunable matching network 116 so that the SMART amplifier circuit is configured to monitor the digital signal output power level received from the ADC 126 and optionally also the temperature level signal and in real-time and adjust the tunable matching network 116 to provide the tuned amplified signal 122 in response thereto.

It is to be appreciated that the SMART amplifier circuit 100 can be configured to operate at intermediate points between the above described operating states to provide a plurality of operating states, which can further result in improved efficiency and linearity. It is also to be appreciated that the processor of the SMART amplifier circuit 100 can further be configured to compensate for operational conditions in addition to temperature, such as for example, aging of the components, radiation effects, and other conditions.

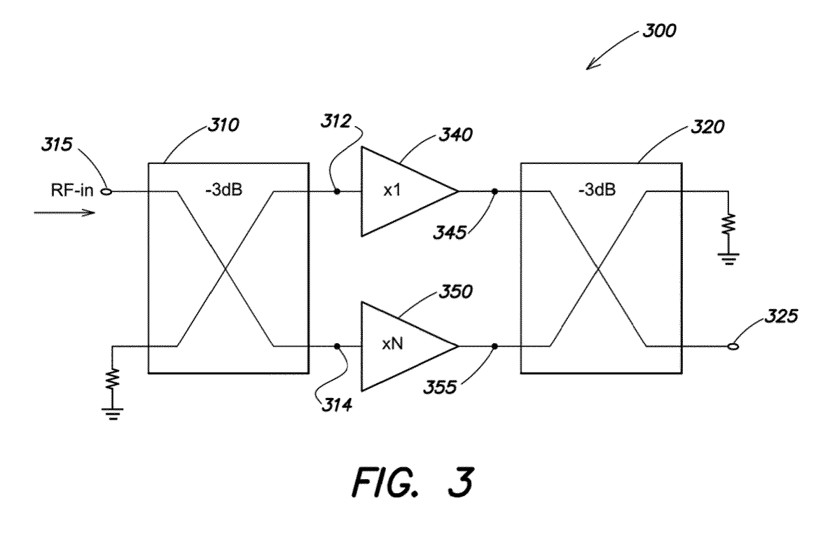

Referring now to FIG. 3, there is illustrated one exemplary embodiment of a power amplifier 106. In particular, there is illustrated one embodiment of a power amplifier circuit 300 that can be used for power amplifier 106, having increased power added efficiency (PAE) and increased linearity at saturation at its output port 325.

The power amplifier circuit 300 includes an input coupler 310 configured to receive an RF input signal 330 at an input port 315, and to generate input coupled signals at input coupler output ports 312, 314. In certain examples, the input coupled signals at input coupler output ports 312 and 314 may be out of phase depending upon, for example, the type of input coupler 310 used in the power amplifier circuit 300. In some embodiments, the input coupler 310 may include Wilkinson power dividers, directional couplers, branch line couplers, balun transformers, and other power splitting or combining means known to those of skill in the art. Four port couplers can, for example, provide a 90° degree phase shift between the input coupled signals presented at input coupler output ports 312 and 314. Wilkinson power dividers and hybrid ring couplers, on the other hand, can provide a 0 or 180 degree phase shift between the input coupled signals presented at input coupler output ports 312 and 314. In the example illustrated in FIG. 3, the input coupled signals at input coupler output ports 312 and 314 may be of equal amplitude. However, in other examples the input coupler may be selected to provide signals with different amplitudes at the input coupler output ports 312 and 314, as discussed further below.

The input coupler output ports 312 and 314 are connected to the input ports of RF amplifiers 340 and 350, respectively, as shown in FIG. 3. The RF amplifiers 340 and 350 can be configured to receive and amplify the input coupled signals so as to generate first and second amplified signals at amplifier output ports 345, 355, respectively. In some embodiments, the RF amplifiers 340 and 350 are each configured to receive and amplify one of the input coupled signals from input coupler ports 312 and 314 substantially independent of any phase shift (e.g., 90° or not) between the input coupled signals, as discussed further below. The RF amplifiers 340 and 350 may be independently and selectively biased into the same or different classes of operation, for example, but not limited to, class A, B, AB, or C operation. As discussed further below, according to certain embodiments, RF amplifier 340 can be designed and biased to receive and amplify one of the input coupled signals from input coupler output port 312 or 314 having relatively low signal levels, and RF amplifier 350 can be designed and biased to receive and amplify the other of the two input coupled signals having relatively high input signal levels. As used herein, the term “relatively low signal levels” is intended to refer to any input power level at which the RF amplifier 340 is in the linear region if biased into class A, B, or AB operation, and any input power level at which the RF amplifier 340 has zero gain if biased into class C operation. As used herein, the term “relatively high signal levels” is intended to refer to any input power level at which the output power of the RF amplifier 350 does not increase in a 1:1 manner (i.e., compressing) if the RF amplifier 350 is biased into class A, B, or AB operation and any input power level at which the RF amplifier 350 has a gain if biased into class C operation.

The RF amplifiers 340 and 350 are connected to an output coupler 320, which is configured to receive the first and second amplified signals and to generate an amplified output signal with improved linearity substantially into saturation. The amplified output signal is provided at the output port 325 of the power amplifier circuit 300. According to certain embodiments, providing the amplified output signal with improved linearity substantially into saturation is achieved by controlling the class of operation, bias, and/or power ratio of the RF amplifiers 340 and 350.

Still referring to FIG. 3, in certain embodiments, the output power characteristics of the RF amplifiers 340 and 350 can be the same, and in other embodiments the output power characteristics of the RF amplifiers 340 and 350 may be different and represented by a power ratio of 1:N, where N represents the normalized power rating. For example, RF amplifier 340 may have an output power of 2 Watts (W) (i.e., RF amplifier 340 is capable of generating a 2 W RF output signal), while RF amplifier 350 may have an output power of 10 W (i.e. RF amplifier 350 is capable of generating a 10 W RF output signal). In this example, N is 5 (given by the output power of RF amplifier 350 divided by the output power of RF amplifier 340).

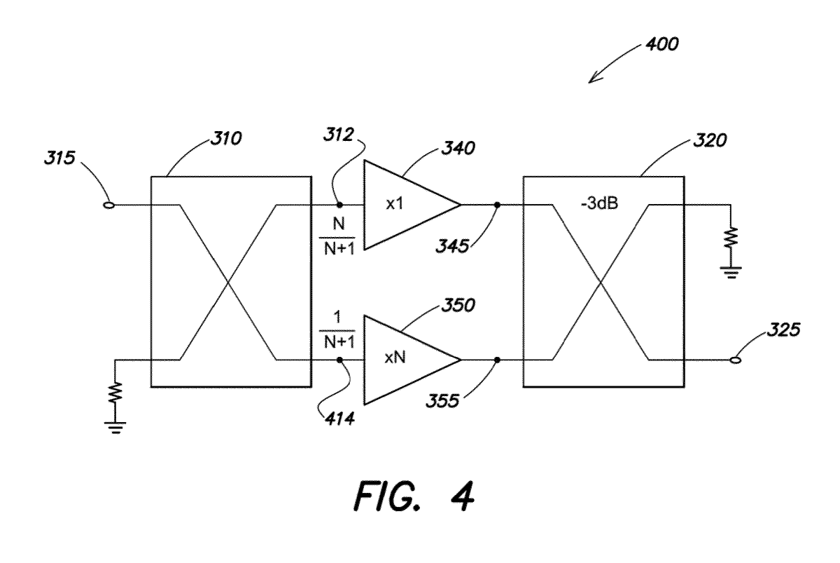

According to certain embodiments, when the output power of RF amplifiers 340 and 350 is represented by a power ratio of 1:N, the coupling factor of the input coupled signals provided at input coupler output ports 312, 314 can remain constant, as shown in FIG. 3. In other words, as discussed above, the amplitudes of the input coupled signals may be the same. In other embodiments, the coupling factor of the input coupled signals may be set to a selected coupling factor, for example [N/(N+1)] and [1/(N+1)], as shown in FIG. 4. In this case, the amplitudes of input coupled signals provided at the input coupler output ports 412, 414 of input coupler 410 may be different and determined according to the coupling factor. It is to be appreciated that the input couplers 310 and 410, shown in FIGS. 3 and 4 respectively, can adjust the coupling factor of the input coupled signals to permit the desired flow of power to RF amplifiers 340, 350. In certain examples, the coupling factor of the input coupled signals can be selected/fixed so as to allow for RF amplifier 340 to turn on substantially at the moment at which RF amplifier 350 compresses, or vice versa.

In the example illustrated in FIG. 4, the power amplifier circuit 400 includes the input coupler 410 having a coupling factor of [N/(N+1)] and [1/(N+1)], while the output coupler 320 is a 3 dB coupler, as may be the case in power amplifier circuit 300. With this particular arrangement, the input coupler 410 and output coupler 320 can be of the same or unequal coupling ratios. Having the input coupler 410 and the output coupler 320 of unequal coupling ratios may, for example, be advantageous if the power amplifier circuit 400 spends most of its time at a particular input power. The input coupler 410 and the output coupler 320 can be also configured to match the output power of RF amplifiers 340 and 350. For example, if RF amplifier 340 is capable of generating a 1 W RF output signal and RF amplifier 350 is capable of generating a 3 W RF output signal, an efficient design may use an input coupler 410 to output coupler 320 ratio of 1:3. This may be achieved using a 1:3 combiner. It will be appreciated by those skilled in the art, given the benefit of this disclosure, that the combiner may be replaced with a splitter.

Additionally, the output coupler 320 may be configured such that the coupling factors at ports 345 and 355 are optimized for a desired point of peak PAE, rather than being equal and ½, ½ (as is the case with a 3 dB coupler), as shown in FIG. 4. For example, if the coupling factor at port 312 is N/(N+1), the coupling factor at port 355 may be set to N/(N+1) for maximum PAE at saturation. Alternatively, the coupling factor at port 355 may be set to 1/(N+1) to achieve maximum PAE at back-off. A designer may select the input power level for peak PAE by selecting a coupling factor between 1/(N+1) and N/(N+1). In all cases, the sum of the coupling factors at ports 345 and 355 is always equal to 1.

According to another embodiment, the RF amplifiers 340 and 350 may have the same output power characteristics but be biased differently such that the measurable output power of the amplifiers 340, 350 is not the same. For example, RF amplifiers 340, 350 can both have the same output power characteristic (e.g., RF amplifiers 340 and 350 are both capable of generating a 10 W RF output signal), but may be configured in a way that the bias of RF amplifier 340 (e.g., the bias of the drain of RF amplifier 340) is set lower than that of RF amplifier 350. With this arrangement, RF amplifier 340 can be configured to have a lower power rating than RF amplifier 350. For example, RF amplifier 340 can be biased to have an output power of 2 W while RF amplifier 350 can be biased to have a 10 W power rating. The above offers the same benefits as using two RF amplifiers 340, 350 of the same output power while providing for easier manufacture. The output power of RF amplifiers 340, 350 can also be varied relative to the magnitude of the RF input signal 330 received at input port 315.

In other embodiments, the power amplifier circuits 300 or 400 may include more than two RF amplifiers. In particular, the power amplifier circuit can be configured to include N number (or a plurality) of RF amplifiers, which can be configured in either series or parallel. In the case of a power amplifier circuit with three amplifiers, for example, a power ratio can be represented by 1:X:Y, with 1 corresponding to a first amplifier, X corresponding to a second amplifier, and Y corresponding to a third amplifier. Additionally, a coupling factor of an amplifier circuit with three amplifiers can be represented by X/(X+Y+1), Y/(X+Y+1), 1/(X+Y+1) for the first amplifier, the second amplifier, and the third amplifier, respectively. Those skilled in the art will appreciate, given the benefit of this disclosure, that the above may be similarly extended to more than three RF amplifiers.

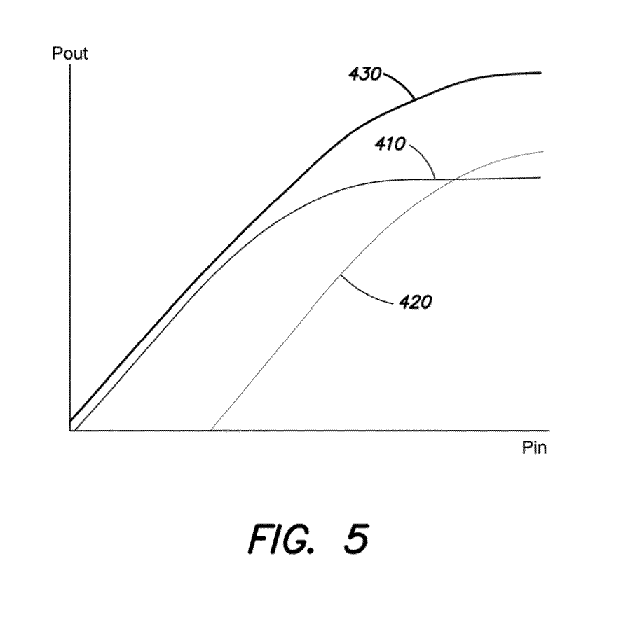

Referring now to FIG. 5, there are illustrated examples of power curves corresponding to the individual RF amplifiers 340, 350, and the power amplifier circuit 300. In FIG. 5, trace 410 represents the power curve for RF amplifier 340, trace 420 represents the power curve for RF amplifier 350, and trace 430 represents the power curve for power amplifier circuit 300. The power curves show the output power (Pout) from the respective amplifier or amplifier circuit as a function of the RF input power (Pin) received at input port 315. The power curves of power amplifier circuit 400 may be the same as or similar to the power curve of power amplifier circuit 300. The power curves 410, 420, and 430 may, for example, be achieved by: (1) biasing RF amplifier 340 into class A, class AB, or class B operation and biasing RF amplifier 350 into class C operation, wherein the power ratings of RF amplifiers 340 and 350 are substantially the same (represented by a 1:1 power ratio); (2) biasing RF amplifiers 340, 350 into the same class (e.g., class A, AB, or B operation), wherein the power ratings of RF amplifiers 340, 350 are substantially different (e.g., represented by a power ratio of 1:N); or (c) a combination of biasing RF amplifiers 340, 350 into the same or a different class of operation with the power ratios between RF amplifiers 340, 350 being dependent on the biasing and class of operation.

For example, at low input power levels, the output power of the power amplifier circuit 300 may be supplied primarily by RF amplifier 340 and secondarily by RF amplifier 350, with the DC power consumed by the power amplifier circuit 300 largely determined by RF amplifier 340. With this particular arrangement, the overall PAE at back-off is relatively high compared with overall PAE at back-off for conventional circuits. At high input power levels, the output power of the power amplifier circuit 300 may be supplied substantially equally by RF amplifiers 340, 350 with each of RF amplifiers 340, 350 operating at peak PAE. With this particular arrangement, the overall PAE is relatively high compared with overall PAE at back-off for conventional amplifier circuits.

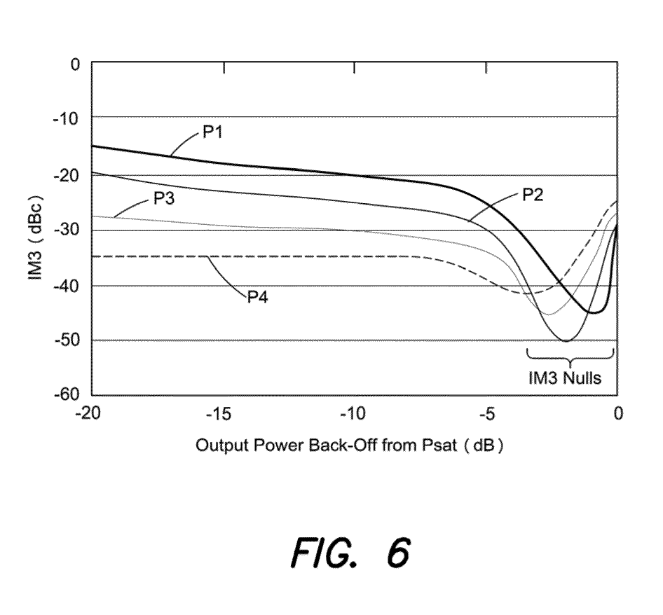

By appropriately selecting the class, bias, and power split ratio of the RF amplifiers 340, 350 in accordance with the concepts and techniques described herein, a power amplifier circuit 300 or 400 may be achieved in which the output power from a first RF amplifier (e.g., RF amplifier 350) becomes more substantial as the output of a second RF amplifier (e.g., RF amplifier 340) begins to compress. With this particular arrangement, the power curve 430 of power amplifier circuit 300 remains linear up to higher power levels. The point at which the power curves 410, 420 of RF amplifiers 340 and 350, respectively, intersect creates a relatively low IM3 point, as shown in FIG. 6. By reconfiguring any combination of the class, bias, and power split ratio of RF amplifiers 340, 350, the IM3 point can be adjusted to a desired input or output level, as illustrated by lines P1, P2, and P3 in FIG. 6. This technique thus achieves linearity deep into saturation while maintaining high efficiency. A 10-20 dB multi-octave linearity improvement has, for example, been shown near saturation. Additionally, the IM3 null may be placed at any desired back-off level. In contrast, dotted line P4 in FIG. 6 represents the traditional output power level associated with conventional circuits in which the two component amplifiers are equal in bias and power ratio, featuring poor linearity at saturation.

It is appreciated that power amplifier circuits employing the concepts and techniques described herein, such as power amplifier circuits 300 and 400, for example, may provide an extremely efficient solution for amplifying the complex modulation schemes employed in current and emerging wireless systems. The ability to reconfigure a minimum IM3 point can be found particularly useful for military and commercial applications where peak linearity over a range of waveforms and power levels are needed. Additionally, unlike conventional amplifier circuits, the power amplifier circuits described herein may also have the advantage of not including bandwidth limiting elements. As discussed above, certain conventional amplifier circuits, rely on a 90° degree phase shift between the two signals provided at the output ports of the input coupler, and are therefore inherently narrowband because the phase shift varies with frequency. In contrast, embodiments of the power amplifier circuits disclosed herein achieve improved PAE at back-off, among other benefits, by changing bias and class of operation, as discussed above. No impedance transformation is necessary, and all the RF amplifiers (carrier, peaking, etc.) may be operating at approximately 50 ohms all the time. The relative phase between the signals provided to the two RF amplifiers 340, 350 is not relevant provided that the signals are not inverse. Accordingly, the bandwidth-limiting frequency dependence of conventional circuits is avoided. Thus, aspects and embodiments may provide power amplifier circuits that are capable of operation over octave, decade, or multi-decade bandwidths while at the same time providing high PAE over a wide dynamic range. Additionally, there are no limits to maximum output power or material selection. For example, the power amplifiers may be fabricated using GaN, GaAs, or SiGe materials.

It is appreciated that the power amplifier (106) can also be any of an envelope-tracked power amplifier, a pulse width modulated power amplifier or other power amplifiers known to those of skill in the art that operate in various operation states. In addition, the power amplifier may also comprise an outphasing amplifier as disclosed in U.S. Provisional Application No. 62/061,423 filed on Oct. 8, 2014 or a Doherty Amplifier with Linearization Circuit and Related Techniques, as disclosed in U.S. application Ser. No. 13/788,824 filed on Mar. 7, 2013, each of which are incorporated herein by reference.

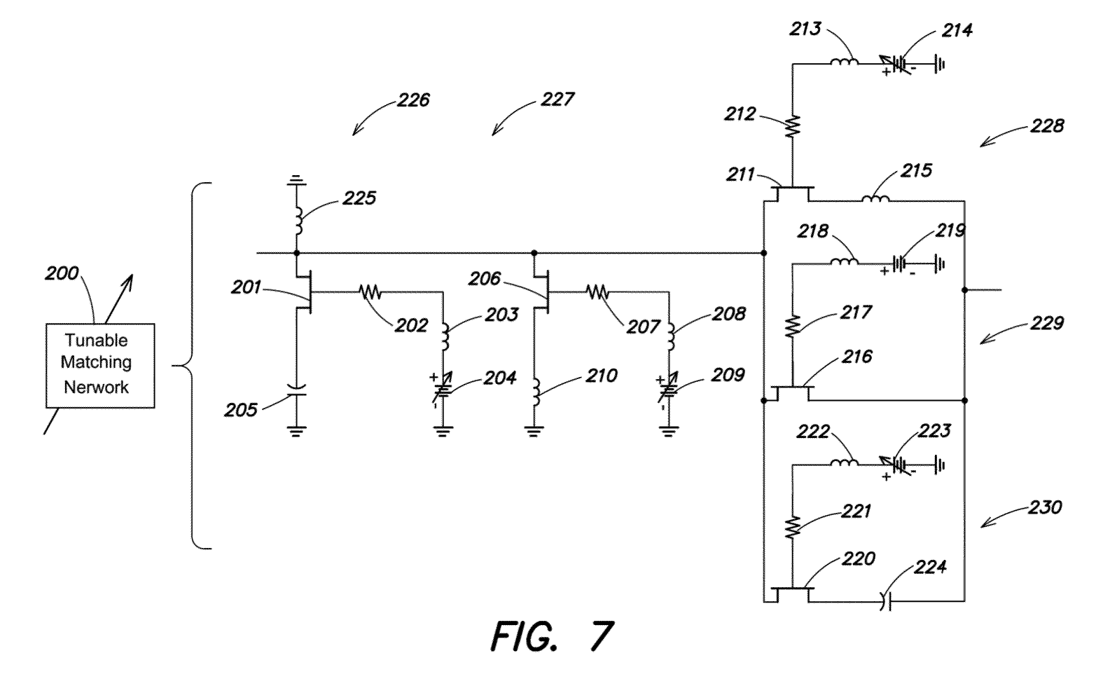

Referring now to FIG. 7, there is illustrated one exemplary embodiment of a Tunable Matching Network (TMN) circuit 200. The TMN circuit includes a plurality sub-circuits, including a sub-circuit 226 for implementing a shunt capacitance, a sub-circuit 227 for implementing a shunt inductance, a sub-circuit 228 for implementing a series inductance, a sub-circuit 230 for implementing a series capacitance, and a sub-circuit 229 for implementing a short circuit for bypassing the series inductance sub-circuit 228 and the series capacitance sub-circuit 230. The plurality of sub-circuits collectively provide a TMN circuit with a customizable tunable impedance range.

The sub-circuit 226 for implementing a shunt capacitance includes at least one field effect transistor (FET) 201 in series with a capacitance 205 to provide a shunt RC sub-circuit. The FET can be varied by the gate control voltage 204 from a full OFF condition of the FET (a pinch-off voltage) corresponding to a high impedance to a full ON condition of the FET (201, 206, 211, 216, 220) corresponding to a low impedance, as well as any voltage in between. The sub-circuit 227 for implementing a shunt inductance includes at least one FET 206 that can be varied with a gate control voltage 209 in series with an inductor 210 to provide a shunt RL sub-circuit. The sub-circuit 228 for implementing a series inductance includes at least one FET 211 that can be varied with a gate control voltage 214 in series with an inductor 215 to provide a series RL sub-circuit. The sub-circuit 230 for implementing a series capacitance includes at least one FET 220 that can be varied with a gate control voltage 223 in series with a capacitor 224 to provide a series RC sub-circuit. The sub-circuit 230 for implementing a short circuit includes at least one FET 216 that can be varied with a gate control voltage 219 to provide a series R sub-circuit that is either a high impedance (substantially an open circuit) or a low impedance (substantially a short circuit) so as to bypass the sub-circuits 228, 230.

Within each sub-circuit (226, 227, 228, 229, 230), there is provided at least one field effect transistor (FET) (201, 206, 211, 216, 220) and a gate bias control voltage (204, 209, 214, 219, 223), which is illustrated as a voltage source in FIG. 7, and which can vary from a bias voltage value (a pinch-off voltage) to provide full OFF condition of the FET (a substantially open circuit) to a voltage value to provide a full ON condition (substantially a short circuit) of the FET (201, 206, 211, 216, 220), as well as voltage in between. It is appreciated that although the gate control voltage values are illustrated as voltage sources, which is one possible way to control the FETs (201, 206, 211, 216, 220) of the sub-circuits (226, 227, 228, 229, 230), according to aspects of embodiments of this disclosure, the gate control voltages are provided by the processor 102 as control signals 118. By varying the respective control voltages (204, 209, 214, 219, 223), the FETs (201, 206, 211, 216, 220) can be configured to provide a variable resistance so as to tune the respective sub-circuit (226, 227, 228, 229, 230) of the impedance matching network. As such, sub-circuits (226, 227, 228, and 230) are configured to be a reconfigurable shunt RC circuit, a reconfigurable shunt RL circuit, a reconfigurable series RL circuit, and a reconfigurable RC circuit, respectively.

Referring again to FIG. 7, resistors (202, 207, 212, 217, 221) are used to isolate the gate control voltage (RF choke) of the sub-circuits (226, 227, 228, 229, 230). Optional inductors (203, 208, 213, 218, and 222) can also be used to isolate the gate control voltage from the source (RF choke). The resistors (202, 207, 212, 217, and 221) and optional inductors (203, 208, 213, 218, and 222) and the gate control voltages (204, 209, 214, 219, and 223) can be varied to collectively adjust the impedance of the TMN circuit along a conductance circle on a Smith chart. Additionally, the TMN includes an inductor 225 to ground provides a ground reference.

It is appreciated that although FIG. 7 illustrates the TMN including FET switching devices, the TMN can also include other switching devices as an alternative to or in addition to the FET devices, such as, for example PIN-diodes, varactor diodes, MEMS devices and other devices known to those of skill in the art.

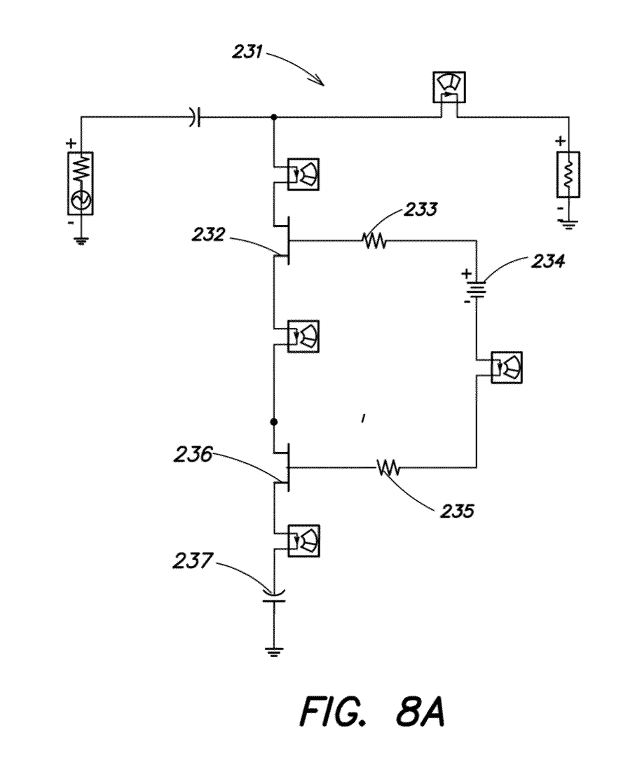

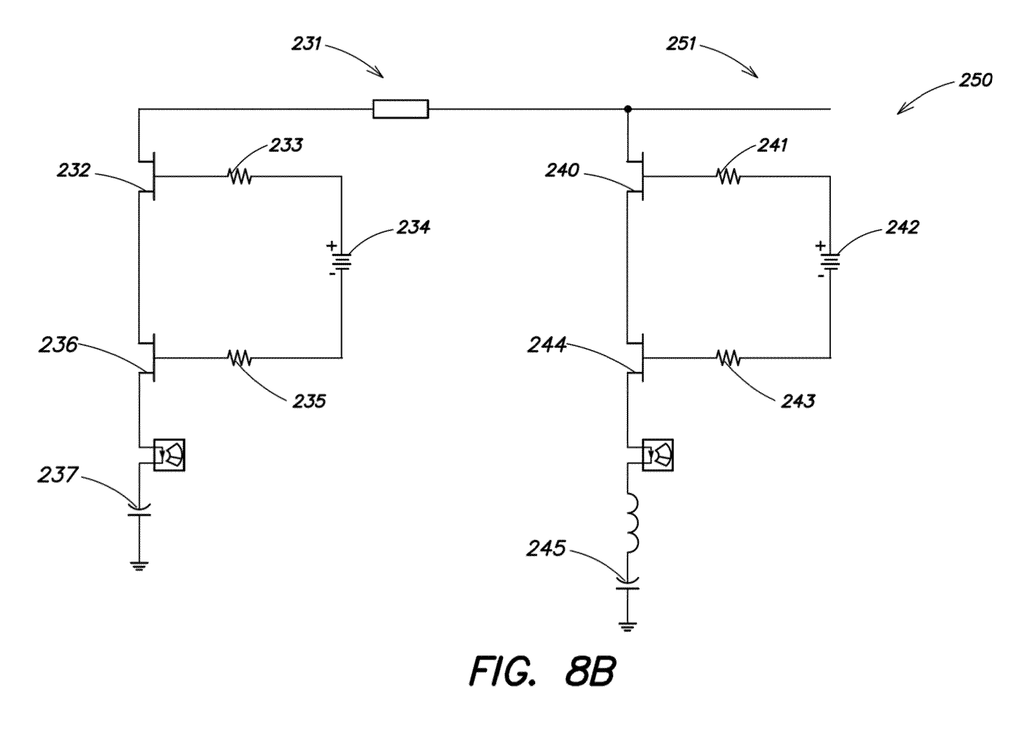

Referring now to FIG. 8A, there is illustrated a schematic diagram of one embodiment of a sub-circuit 231 of the TMN circuit of FIG. 7 that includes a plurality of stacked FETs (232, 236), which can be used to handle higher power applications of the sub-circuit. The exemplary TMN sub-circuit 231 can further include a floating voltage source 234 to bias the FETs (232, 236) as discussed above. The exemplary TMN sub-circuit 231 can further include resistors 233, 235 used to isolate the gate control voltage 234. This exemplary TMN sub-circuit 231 further illustrates a capacitor 237 in series with the FETs (232, 236) to provide a shunt RC sub-circuit 231. The capacitor 237 can, for example, be a barium strontium titanate (BST) capacitor, which has a permittivity that depends on the applied electric field and a high dielectric constant so that large capacitances can be realized in a relatively small area.

It is to be appreciated that the same sub-circuit 231 can be used to implement a higher power shunt RL sub-circuit with a series inductance with the stacked FETs (232, 236), a higher power series RC with a series capacitance with the stacked FETs (232, 236), and higher power series RL circuit with a series inductance with the stacked FETs (232, 236).

Referring now to FIG. 8B, there is illustrated a schematic diagram of another embodiment of a higher power sub-circuit 250 of the TMN circuit of FIG. 7 that includes both a stacked FET (232, 236) shunt RC circuit 231 as illustrated in FIG. 8A, and a stacked FET (240, 244) shunt RC circuit 251 disposed in parallel to sub-circuit 231. The sub-circuit 251 can further include a floating voltage source 242 to bias the FETs (240, 244) as discussed above. The sub-circuit 251 can further include resistors 241, 243 used to isolate the gate control voltage 242. The sub-circuit 251 can further include a capacitor 245 in series with the FETs (240, 244) to provide the parallel shunt RC sub-circuit 251. It is to be appreciated that the sub-circuit 250 can also be used to implement a higher power shunt RL sub-circuit with a series inductance, a higher power series RC with a series capacitance, and higher power series RL circuit with a series inductance.

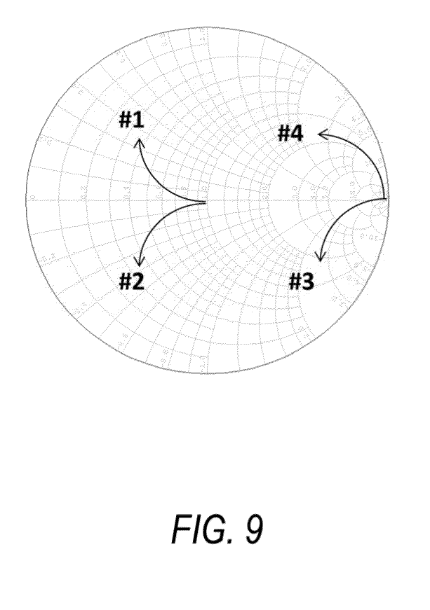

Theoretical operation of the TMN will now be discussed. As noted above, as the gate control voltages of the sub-circuits are changed, the impedance collectively presented by the TMN circuit changes. Pinching-off a FET makes the FET substantially an open circuit and the component connected in series to it ineffective. Referring to FIG. 9, there is illustrated tuning of a theoretical TMN by using one of the subs-circuits, or in other words single element (sub-circuit tuning). Thus, if all of the FETs but one FET of one sub-circuit (or if only one sub-circuit is used) are pinched-off, the TMN circuit impedance will rotate around the Smith chart along an arc in one direction as gate bias voltage to the respective FET changes (as shown by the arcs identified as #1, #2, #3, #4). If all of the sub-circuits are turned on in various combinations, the entire Smith chart can be presented by the TMN (the entire Smith chart could be covered).

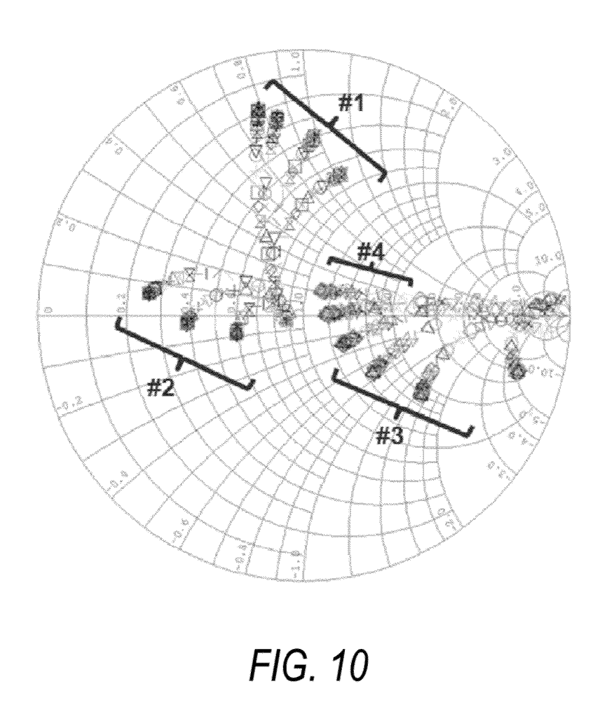

Referring to FIG. 10, shown are example measurement results of the TMN circuit 200 of FIG. 7 with each sub-circuit (226, 227, 228, 229, 230) being used independently. With this particular arrangement, substantially all FETs are pinched-off and each branch comprises a different component value. If more than one FET is turned-on (or more than one sub-circuit is used), the TMN circuit impedance will rotate around the Smith chart in multiple directions. Thus, if all of the sub-circuits in FIG. 7 are turned on in various combinations, the entire Smith chart can be presented by the TMN (the entire Smith chart could be covered).

It is appreciated that the inductor and capacitor component values as well as the type of FET and size of the FET can be chosen to determine the Smith Chart coverage area and shape. It is also appreciated that tuning components of the exemplary TMN's circuit disclosed herein are not limited to capacitors and inductors. For example, resistors and delay lines can also be suitable. Additionally, it is to be appreciated that the tuning components themselves can also be made variable to provide for an additional dimension of re-configurability. For example, an adjustable capacitor can be used to further tune the impedance of the TMN circuit such that the combined impedance of the TMN circuit and RF circuit component (e.g., Power Amplifier 106) can be more closely matched to an impedance of a source.

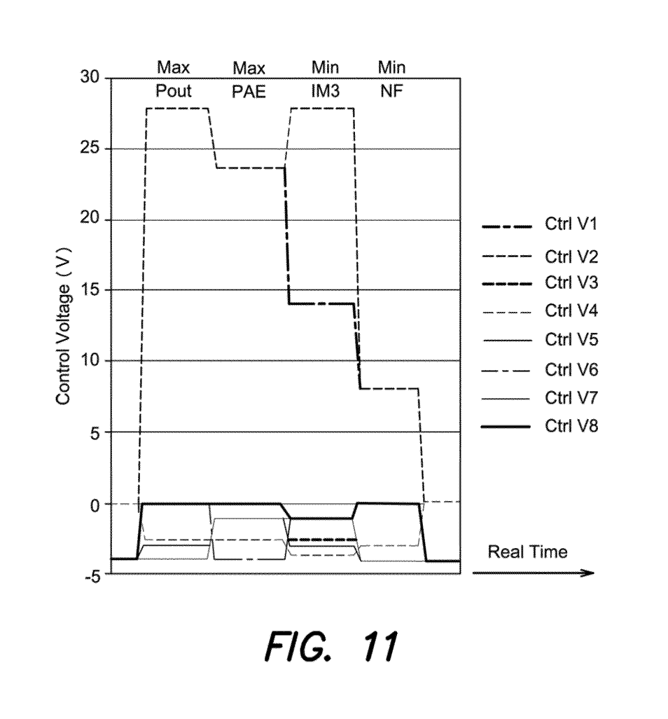

Referring now to FIG. 11, there is illustrated a graph of the response of the exemplary tunable matching network of FIG. 2 versus time in response to various control signals received from a control line. The frequency response of the tunable matching network (116 shown in FIG. 1) can be adjusted to match the desired output of the SMART amplifier circuit (100, shown in FIG. 1). For example, the tunable matching network 116 can be configured to receive a control signal from a control line (118, shown in FIG. 1) and tune the amplified signal (112, shown in FIG. 1) received from the power amplifier (106, shown in FIG. 1) in accordance with a desired output power (Pout), power added efficiency (PAE), third order intermodulation (IM3), and/or noise figure (NF) bias voltage in real-time, to produce a tuned amplified signal (122, shown in FIG. 1).

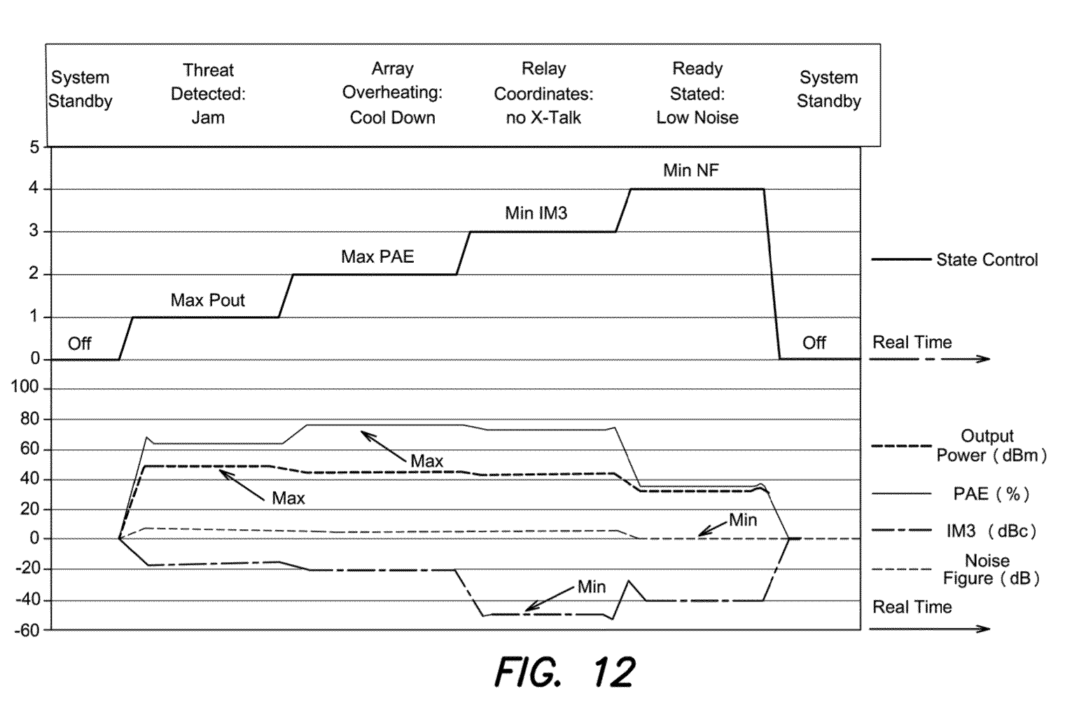

Referring now to FIG. 12, there is illustrated a graph an example output of the SMART amplifier circuit 100 as function of the state control signal of the state control line (136, shown in FIG. 1), which is configured to meet different system performance needs (e.g., peak power, efficiency, linearity, noise). The SMART amplifier circuit (100, shown in FIG. 1) responds to the state control signal on line 136 accordingly by adjusting any combination of the output power, the PAE, the IM3 point, noise figure, and the like. By changing the power amplifier circuit 106 bias and matching impedance presented by the tunable matching network 116, the SMART amplifier circuit 100 can meet the needs of the system where the SMART amplifier circuit 100 is being utilized in real time. The impedance of the tunable matching network of FIG. 2 and the bias voltages illustrated in FIG. 11 were used to generate the plot of FIG. 12.

With the above described arrangement, the SMART amplifier circuit (100, shown in FIG. 1) can be configured to adjust in real-time to maintain optimal performance based upon changing operation needs. For example, the SMART amplifier circuit 100 can adjust its peak power, linearity, efficiency, bandwidth, and noise to maintain optimal performance. As such, the SMART amplifier circuit 100 is suitable for example radar, electronic warfare (i.e., jamming), communication, and signals intelligence (SIGINT) applications, alleviating the need for specialized modules for each application.

The SMART amplifier circuit 100 can also be configured to make decisions at a component level, which can speed up adaption to the system needs and greatly improve reaction time over, for example, the decisions made at a system level. Additionally, the SMART amplifier circuit 100 can include a decision aid component operative to provide decision advice and decision prompts in response a current situation and need. Decision data may, for example, be provided to the decision aid component automatically through an algorithm or alternatively through a user response to a decision prompt.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

What is claimed is:

1. An amplifier circuit, comprising:
a processor configured to receive a state control signal and generate a plurality of control signals;
a power amplifier configured to receive at a first input an RF input signal and at second input a first control signal, and configured to provide an amplified RF signal as an output signal that is a function of the RF input signal and the first control signal and that can be changed as a function of the RF input signal and the first control signal; and
a tunable matching network configured to receive a second control signal as a first input and the amplified RF signal as a second input and to provide a tuned, amplified RF output signal as an output that is a function of the amplified RF signal and the second control signal and that can be changed as a function of the amplified RF signal and the second control signals.

2. The amplifier circuit of claim 1, further comprising:
a temperature sensor having an output coupled to the processor and configured to provide a temperature signal to the processor, wherein the processer is configured to receive the temperature signal and to provide the first control signal and the second control signal as function of the temperature signal.

3. The amplifier circuit of claim 2, further comprising:
a first coupler having an input coupled to an input of the power amplifier and an output for providing a coupled signal from the input of the power amplifier;
a first analog-to-digital converter (ADC) having an input coupled to the output of the coupler and having an output providing a first ADC signal to the processor;
wherein the processer is configured to receive first ADC signal and to provide the first control signal and the second control signal as function of the first ADC signal.

4. The amplifier circuit of claim 3, further comprising:
a second coupler having an input coupled to an output of the tunable matching network and an output for providing a coupled signal from the output of the tunable matching network;
a second analog-to-digital converter (ADC) having an input coupled to the output of the second coupler an output providing a second ADC signal to the processor;
wherein the processer is configured to receive the second ADC signal and to provide the first control signal and the second control signal as function of the second ADC signal.

5. The amplifier circuit of claim 1, further comprising:
a first coupler having an input coupled to an input of the power amplifier and an output for providing a coupled signal from the input of the power amplifier; and
a first analog-to-digital converter (ADC) having an input coupled to the output of the first coupler and having an output providing a first ADC signal to the processor;
wherein the processer is configured to receive first ADC signal and to provide the first control signal and the second control signal as function of the first ADC signal.

6. The amplifier circuit of claim 5, further comprising:
a second coupler having an input coupled to an output of the tunable matching network and an output for providing a coupled signal from the output of the tunable matching network; and
a second analog-to-digital converter (ADC) having an input coupled to the output of the second coupler an output providing a second ADC signal to the processor;
wherein the processer is configured to receive the second ADC signal and to provide the first control signal and the second control signal as function of the second ADC signal.

7. The amplifier circuit of claim 1, wherein the processor is configured, in response to the a state control signal, to provide the first control signal to set the bias of the power amplifier to a maximum operating value so as to provide a maximum power out, and to provide the second control signal to the tunable matching network to provide a Maximum Power Out (Max Pout) impedance to the output of the Power Amplifier.

8. The amplifier circuit of claim 1, wherein the processor is configured, in response to the a state control signal, to provide the first control signal to set the bias of the power amplifier to any of class F, F⁻¹, or J operation, and to provide the second control signal to the tunable matching network to provide a Maximum Power Added Efficiency (Max PAE) impedance to the output of the Power Amplifier.

9. The amplifier circuit of claim 1, wherein the processor is configured, in response to the a state control signal, to provide the first control signal to set the bias of the power amplifier is biased to any of class AB or B operation, and to provide the second control signal to the tunable matching network to provide a Maximum Power Added Efficiency (Max PAE) impedance to the output of the Power Amplifier.

10. The amplifier circuit of claim 1, wherein the processor is configured, in response to the a state control signal, to provide the first control signal to set the bias of the power amplifier so as to reduce the spurious nature of the output signal from the Power Amplifier, and to provide the second control signal to the tunable matching network to provide a minimum third order intermodulation (Min IM3) impedance to the output of the Power Amplifier.

11. The amplifier circuit of claim 1, wherein the processor is configured, in response to the a state control signal, to provide the first control signal to set the bias of the power amplifier so as to provide a third order intermodulation point IM3 at a desired operating power, and to provide the second control signal to the tunable matching network to provide a minimum third order intermodulation (Min IM3) impedance to the output of the Power Amplifier.

12. The amplifier circuit of claim 1, wherein the processor is configured, in response to the a state control signal, to provide the first control signal to set the bias of the power amplifier to reduce the voltage output of the amplified signal at the output of the power amplifier, and to provide the second control signal to the tunable matching network to provide a Minimum Noise (NFₘᵢₙ) impedance to the output of the Power Amplifier.

13. The amplifier circuit of claim 1, wherein the tunable matching network circuit, comprises:
a first sub-circuit implementing a reconfigurable shunt RC circuit;
a second sub-circuit implementing a reconfigurable shunt RL circuit;
a third sub-circuit implementing a reconfigurable series RL circuit;
a fourth sub-circuit implementing a reconfigurable series RC circuit; and
a fifth sub-circuit implementing a series short circuit for bypassing the third sub-circuit and the fourth sub-circuit;
wherein each sub-circuit comprises one or more FET's configured to provide a variable impedance for adjusting a tunable range of the tunable matching network circuit.

14. The amplifier circuit of claim 13, wherein the first sub-circuit of the tunable matching network circuit comprises at least one field effect transistor (FET) in series with a capacitance to provide a shunt RC sub-circuit.

15. The amplifier circuit of claim 13, wherein the second sub-circuit of the tunable matching network circuit comprises at least one field effect transistor (FET) in series with an inductor to provide a shunt RL sub-circuit.

16. The amplifier circuit of claim 13, wherein the third sub-circuit of the tunable matching network circuit comprises at least one field effect transistor (FET) in series with an inductor to provide a series RL sub-circuit.

17. The amplifier circuit of claim 13, wherein the fourth sub-circuit of the tunable matching network circuit comprises at least one field effect transistor (FET) in series with a capacitor to provide a series RC sub-circuit.

18. The amplifier of claim 13, wherein the fifth sub-circuit of the tunable matching network circuit comprises at least one field effect transistor (FET) that can be varied with a gate control voltage to provide substantially a short circuit so as to bypass the third and fourth sub-circuits or an open circuit so as to not bypass the third and fourth sub-circuits.

19. The amplifier circuit of claim 13, wherein the at least one field effect transistor (FET) of any of the first sub-circuit, the second sub-circuit, the third sub-circuit, the fourth sub-circuit, and the fifth sub-circuit of the tunable matching network circuit can be varied with a gate control voltage to provide the variable impedance value that can be substantially an open circuit, substantially a short circuit, or an impedance value there between.

20. The amplifier circuit of claim 13, wherein at least one of the first sub-circuit, second sub-circuit, third sub-circuit, fourth sub-circuit, and fifth sub-circuit of the tunable matching network circuit comprises:
at least two stacked FETs;
a floating gate bias voltage source; and
a plurality of resistors arranged to isolate the floating gate bias voltage source.

21. The amplifier circuit of claim 1, wherein the power amplifier circuit, comprises:
an input coupler configured to receive an RF input signal and to generate at least two coupled signals;
a first RF amplifier configured to receive and amplify a first one of the at least two coupled signals to generate a first amplified signal, the first RF amplifier being biased into a first class of operation;
a second RF amplifier configured to receive and amplify a second one of the at least two coupled signals to generate a second amplified signal, the second RF amplifier being biased into a second class of operation; and
an output coupler configured to receive the first and second amplified signals and to generate an amplified output signal based on the first and second amplified signals;
wherein a power ratio between the first and second RF amplifiers is selected based on biasing of the first and second RF amplifiers, the first class of operation, and the second class of operation.

22. The amplifier circuit of claim 21, wherein the first class of operation is one of class A, class AB, and class B, and the second class of operation is class C.

23. The amplifier circuit of claim 22, wherein the power ratio is 1:1.

24. The amplifier circuit of claim 23, wherein the input coupler and the output coupler are 3 dB couplers.

25. The amplifier circuit of claim 21, wherein the first class of operation is the same as the second class of operation, and wherein the first RF amplifier has a normalized power rating of 1 and the second RF amplifier has a normalized power rating of N, such that the power ratio is 1:N.

26. The amplifier circuit of claim 25, wherein the input coupler and the output coupler are 3 dB couplers.

27. The amplifier circuit of claim 25, wherein the input coupler has an input coupling factor selected to match the power ratio.

28. The amplifier circuit of claim 27, wherein the output coupler has an output coupling factor selected to match the power ratio.

29. The amplifier circuit of claim 25, wherein the input coupler is configured to provide the first one of the at least two coupled signals at a first port with a coupling factor of N/(N+1), and to provide the second one of the at least two coupled signals at a second port with a coupling factor of 1/(N+1), and wherein the first RF amplifier is connected to the first port to receive the first one of the at least two coupled signals, and the second RF amplifier is connected to the second port to receive the second one of the at least two coupled signals.

30. The amplifier circuit of claim 29, wherein the output coupler is a 3 dB coupler.

31. The amplifier circuit of claim 29, wherein the output coupler has a first input port connected to an output of the first RF amplifier to receive the first amplified signal, and a second input port connected to an output of the second RF amplifier to receive the second amplified signal, and the output coupler is configured with a coupling factor of N/(N+1) at the second input port and a coupling factor of [1−N/(N+1)] at the first input port.

32. The amplifier circuit of claim 29, wherein the output coupler has a first input port connected to an output of the first RF amplifier to receive the first amplified signal, and a second input port connected to an output of the second RF amplifier to receive the second amplified signal, and the output coupler is configured with a coupling factor of 1/(N+1) at the second input port and a coupling factor of [1−1/(N+1)] at the first input port.

33. The amplifier circuit of claim 21, wherein the first RF amplifier and the second RF amplifier are substantially the same and are biased differently such that the power ratio is less than or greater than one.
